(19) United States
(12) Patent Application Publication
(10) Pub. No.: US 2026/0215021 A1
(43) Pub. Date: Jul. 23, 2026

(54) PHOTOELECTRIC CONVERSION PANEL, METHOD FOR MANUFACTURING PHOTOELECTRIC CONVERSION PANEL, AND X-RAY IMAGING APPARATUS

(71) Applicant: SHARP KABUSHIKI KAISHA, Osaka (JP)

(72) Inventors: MAKOTO NAKAZAWA, Osaka (JP); RIKIYA TAKITA, Osaka (JP)

(21) Appl. No.: 19/440,846

(22) Filed: Jan. 6, 2026

(30) Foreign Application Priority Data
Jan. 10, 2025 (JP) 2025-004264

(51) Int. Cl. H10F 39/00; H10F 39/18

(52) U.S. Cl. CPC H10F 39/811; H10F 39/016; H10F 39/1898

(57) ABSTRACT

A photoelectric conversion panel includes a photodiode including a lower electrode layer and an upper electrode layer and a first insulating film located over the photodiode. The upper electrode layer has an electrode section and an opening, and the first insulating film covers the opening.

### BACKGROUND

### 1. Field

The present disclosure relates to a photoelectric conversion panel.

### 2. Description of the Related Art

Japanese Unexamined Patent Application Publication No. 2017-83218 discloses a photoelectric conversion panel obtained by stacking an n-type silicon layer, an i-type silicon layer, a p-type silicon layer, a transparent electrode layer, and a transparent insulating layer in this order.

The conventional photoelectric conversion panel undesirably suffers from a decrease in photoelectric conversion accuracy due to delamination of the transparent insulating layer from the transparent electrode layer.

### SUMMARY

According to an aspect of the disclosure, there is provided a photoelectric conversion panel including a photodiode including a lower electrode layer and an upper electrode layer and a first insulating film located over the photodiode. The upper electrode layer has an electrode section and an opening, and the first insulating film covers the opening.

According to an aspect of the disclosure, there is provided a photoelectric conversion panel including a photodiode including a lower electrode layer and an upper electrode layer and a first insulating film located over the photodiode. The upper electrode layer has a plurality of electrically connected electrode sections that are adjacent to each other via a gap portion, and the first insulating film covers the gap portion.

### BRIEF DESCRIPTION OF THE DRAWINGS

FIG. 1 is a cross-sectional view showing an example configuration of a photoelectric conversion panel according to the present embodiment;

FIG. 2 is a plan view showing the example configuration of the photoelectric conversion panel according to the present embodiment;

FIG. 3 is a schematic view showing an example configuration of a photoelectric conversion device according to the present embodiment;

FIG. 4 is a schematic view showing an example configuration of an X-ray imaging apparatus according to the present embodiment;

FIG. 5 is a table showing a relationship between a structure of an upper electrode layer and external quantum efficiency;

FIG. 6 is a flow chart showing a method for manufacturing a photoelectric conversion panel according to the present embodiment;

FIG. 7 is a cross-sectional view showing the method for manufacturing a photoelectric conversion panel according to the present embodiment;

FIG. 8 is a cross-sectional view showing the method for manufacturing a photoelectric conversion panel according to the present embodiment;

FIG. 9 is a cross-sectional view showing the method for manufacturing a photoelectric conversion panel according to the present embodiment;

FIG. 10 is a cross-sectional view showing the method for manufacturing a photoelectric conversion panel according to the present embodiment;

FIG. 11 is a cross-sectional view showing the method for manufacturing a photoelectric conversion panel according to the present embodiment;

FIG. 12 is a cross-sectional view showing an example configuration of a photoelectric conversion panel according to the present embodiment;

FIG. 13 is a cross-sectional view showing an example configuration of a photoelectric conversion panel according to the present embodiment;

FIG. 14 is a plan view showing the example configuration of the photoelectric conversion panel according to the present embodiment; and

FIG. 15 is a flow chart showing a method for manufacturing a photoelectric conversion panel shown in FIGS. 13 and 14.

### DESCRIPTION OF THE EMBODIMENTS

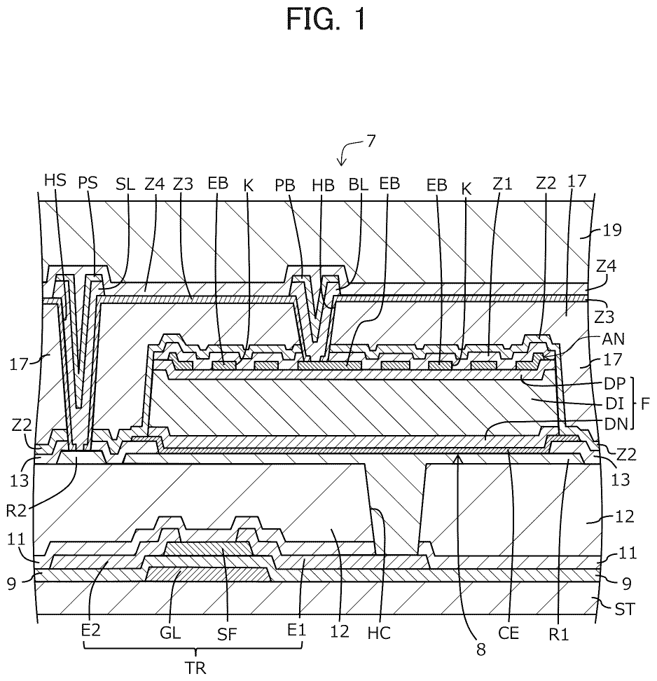

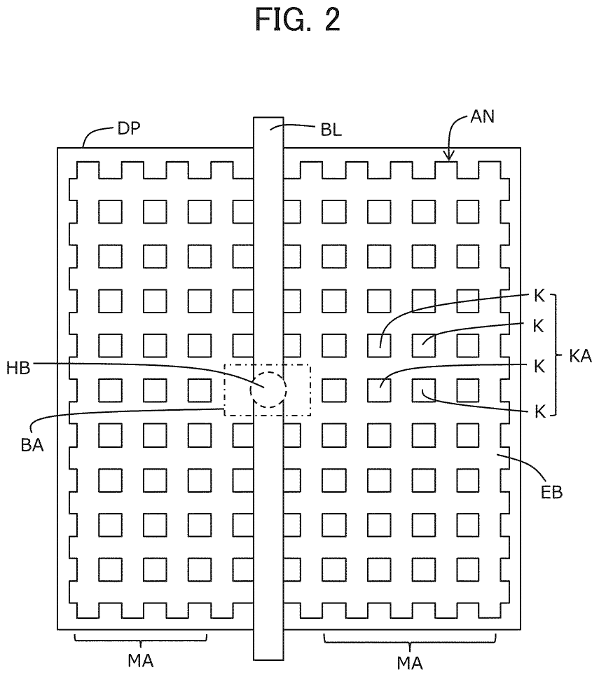

FIG. 1 is a cross-sectional view showing an example configuration of a photoelectric conversion panel according to the present embodiment. FIG. 2 is a plan view showing the example configuration of the photoelectric conversion panel according to the present embodiment. As shown in FIGS. 1 and 2, the photoelectric conversion panel 7 according to the present embodiment includes a photodiode 8 including a lower electrode layer CE and an upper electrode layer AN and a first insulating film Z1 located above the photodiode 8. The upper electrode layer AN has an electrode section EB and an opening K, and the first insulating film Z1 covers the opening K. This brings the electrode section EB and a foundation of the upper electrode layer AN (e.g. a type 3 layer DP of the photodiode 8) into direct contact with each other in the opening K, thus enhancing adhesion between the first insulating film Z1 and the upper electrode layer AN. This makes it difficult for the first insulating film Z1 to delaminate from the upper electrode layer AN and brings about improvement in photoelectric conversion accuracy of the photoelectric conversion panel 7.

In the photoelectric conversion panel 7 shown in FIGS. 1 and 2, a scanning line GL, a gate insulating film 9, a semiconductor layer SF, first and second conductive electrodes E1 and E2, a lower passivation film 11, an interlayer insulating film 12, first and second relay electrodes R1 and R2, an upper passivation film 13, the lower electrode layer CE, a functional layer F containing a semiconductor, the upper electrode layer AN, the first insulating film Z1, a second insulating film Z2, a planarizing film 17, a third insulating film Z3, a bias line BL, a data line SL, transparent electrodes PB and PS, a fourth insulating film Z4, and a protective film 19 are arranged in this order over a substrate ST.

The photodiode 8 includes the lower electrode layer CE, the upper electrode layer AN, and the functional layer F, which is located between the lower electrode layer CE and the upper electrode layer AN. The functional layer F is formed by stacking a type 1 layer DN, a type 2 layer DI, and the type 3 layer DP in this order from bottom. The type 1 layer DN may be a N-type doped N-type semiconductor layer. The type 2 layer DI may be non-doped intrinsic semiconductor layer. The type 3 layer may be a P-type doped P-type semiconductor layer. The functional layer F may be a silicon-containing semiconductor layer.

Part of the scanning line GL (gate electrode), the semiconductor layer SF (channel), and the first and second conductive electrodes E1 and E2 constitute a transistor TR. The lower electrode layer CE may be connected to the first conductive electrode E1 via the first relay electrode R1 and a contact hole HC. The contact hole HC is bored through the lower passivation film 11 and the interlayer insulating film 12. The second conductive electrode E2 may be connected to the data line SL via the second relay electrode R2 and a contact hole HS. The contact hole HS is bored through the upper passivation film 13, the second insulating film Z2, the planarizing film 17, and the third insulating film Z3. The semiconductor layer SF may contain an oxide semiconductor (e.g. an indium gallium zinc oxide).

The lower electrode layer CE may function as a cathode of the photodiode 8. The electrode section EB of the upper electrode layer AN is electrically connected to the bias line BL via a contact hole HB. The contact hole HB is bored through the first insulating film Z1, the second insulating film Z2, the planarizing film 17, and the third insulating film Z3. The electrode section EB may function as an anode of the photodiode 8. The electrode section EB of the upper electrode layer AN has translucency. The transparent electrode PB may be located over the bias line BL, and the transparent electrode PS may be located over the data line SL. The electrode section EB and the transparent electrodes PB and PS may be made of ITO (indium tin oxide or IZO (indium zinc oxide).

The gate insulating film 9 and the lower and upper passivation films 11 and 13 may be inorganic insulating films (e.g. silicon nitride films or silicon oxide films). The first to fourth insulating films Z1 to Z4 may be inorganic insulating films (e.g. insulating films containing at least either a silicon nitride or a silicon oxide). The interlayer insulating film 12, the planarizing film 17, and the protective film 19 may be organic insulating films (e.g. resin films of polyimide or other types of resin). The bias line BL and the data line SL may be metal films (e.g. containing at least one of titanium, aluminum, molybdenum, copper, and gold). The type 3 layer DP of the functional layer F may be a p-type silicon layer.

As shown in FIG. 1, in the photoelectric conversion panel 7, the first insulating film Z1 and the type 3 layer DP of the functional layer F may be in contact with each other in the opening K of the upper electrode layer AN. As shown in FIG. 2, the upper electrode layer AN may have a group of openings KA including the opening K, and the group of openings KA may be arranged in a matrix. As shown in FIGS. 1 and 2, the upper electrode layer AN may include a mesh region MA including a plurality of openings K and a solid electrode region BA not including the opening K, and the solid electrode region BA may be connected to the bias line BL via the contact hole HB. The solid electrode region BA may be smaller than the mesh region MA. The solid electrode region BA may be surrounded by the mesh region MA. As shown in FIG. 1, in the photoelectric conversion panel 7, the second insulating film Z2 may cover a side face of the functional layer F (i.e. the type 1 to 3 layers DN, DI, and DP).

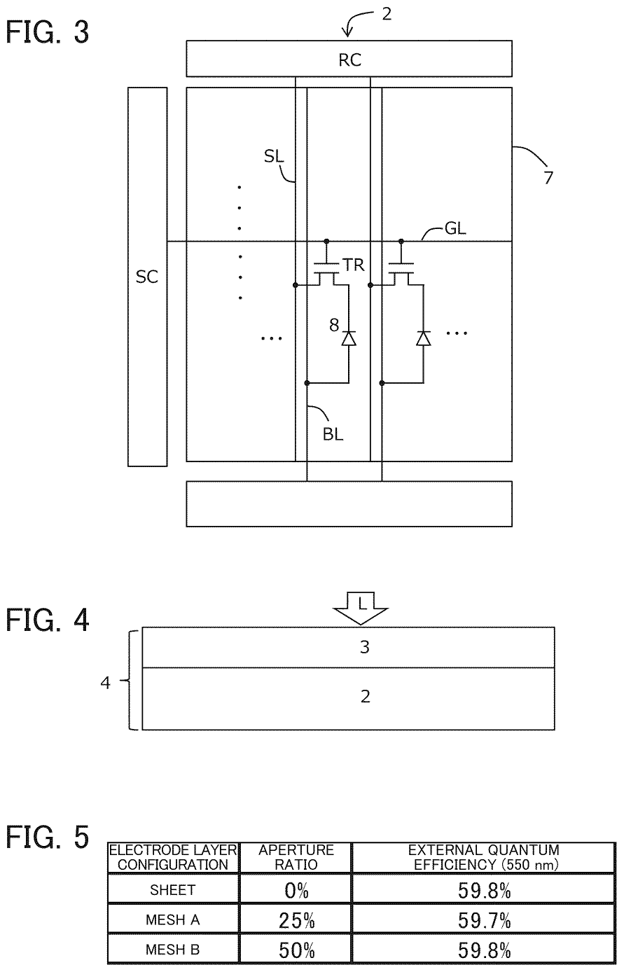

FIG. 3 is a schematic view showing an example configuration of a photoelectric conversion device according to the present embodiment. The photoelectric conversion device 2 according to the present embodiment includes the photoelectric conversion panel 7, a readout circuit RC connected to the data line SL, a scanning circuit SC connected to the scanning line GL, and a voltage supply circuit BC connected to the bias line BL. In the photoelectric conversion device 2, in a period during which the scanning line GL is selected, an electric current corresponding to the amount of light received by the photodiode 8 is outputted to the readout circuit RC via the lower electrode layer CE and the transistor TR (i.e. the first conductive electrode E1, the semiconductor layer SF, and the second conductive electrode E2).

FIG. 4 is a schematic view showing an example configuration of an X-ray imaging apparatus according to the present embodiment. The X-ray imaging apparatus 4 according to the present embodiment includes the photoelectric conversion device 2 and a scintillator 3. An X-ray L having passed through an object to be imaged is converted by the scintillator 3 into light of a predetermined wavelength region (scintillation light), and the scintillation light enters the photoelectric conversion device 2 (i.e. the functional layer F through the upper electrode layer AN of the photoelectric conversion panel 7).

FIG. 5 is a table showing a relationship between a structure of an upper electrode layer and external quantum efficiency. As shown in FIG. 5, for light of a wavelength of 550 [nm], the external quantum efficiency of a mesh electrode A (with an aperture ratio of 25%) and a mesh electrode B (with an aperture ratio of 50%) is not much different from the external quantum efficiency of a sheet electrode (with an aperture ratio of 0%). That is, it is found that providing the upper electrode layer AN with the opening K for a reduction in delamination of the first insulating film Z1 does not have a real adverse effect on conversion efficiency.

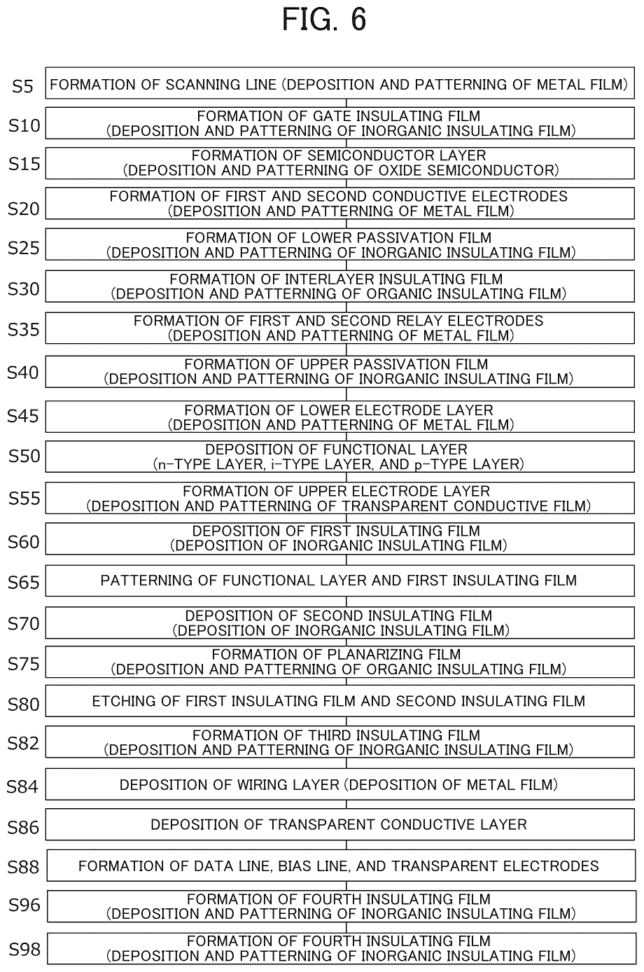

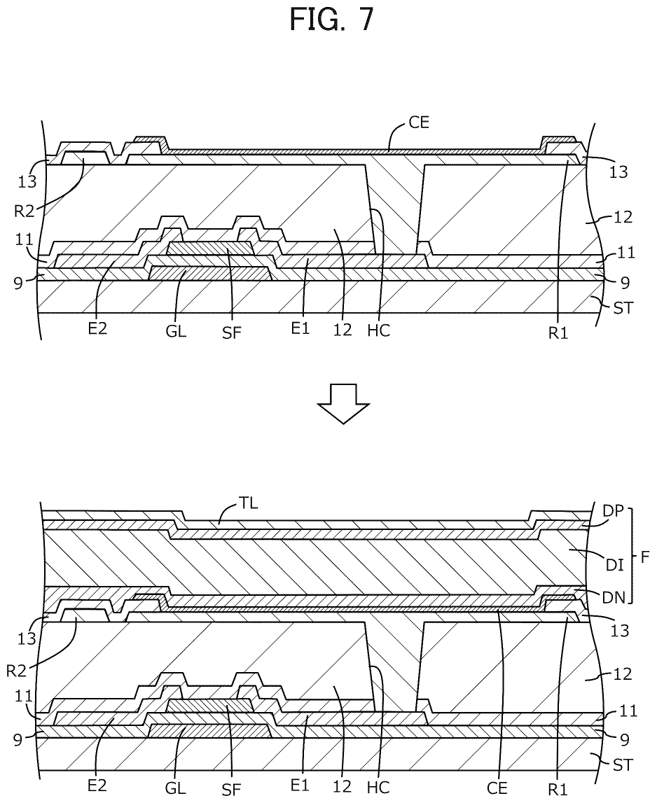

FIG. 6 is a flow chart showing a method for manufacturing a photoelectric conversion panel according to the present embodiment. FIGS. 7 to 11 are cross-sectional views showing the method for manufacturing a photoelectric conversion panel according to the present embodiment. The following patterning may include a photolithography step. In S5, the formation of a scanning line GL (i.e. the deposition and patterning of a metal film) is executed. In S10, the formation of a gate insulating film 9 (i.e. the deposition and patterning of an inorganic insulating film) is executed. In S15, the formation of a semiconductor layer SF (i.e. the deposition and patterning of an oxide semiconductor) is executed. In S20, the formation of first and second conductive electrodes E1 and E2 (i.e. the deposition and patterning of a metal film) is executed.

In S25, the formation of a lower passivation film 11 (i.e. the deposition and patterning of an inorganic insulating film) is executed. In S30, the formation of an interlayer insulating film 12 (i.e. the deposition and patterning of an organic insulating film) is executed. In S35, the formation of first and second relay electrodes R1 and R2 (i.e. the deposition and patterning of a metal film) is executed. In S40, the formation of an upper passivation film 13 (i.e. the deposition and patterning of an inorganic insulating film) is executed.

In S45, the formation of a lower electrode layer CE (i.e. the deposition and patterning of a metal film) is executed. In S50, the deposition of a functional layer F (i.e. an n-type layer, an i-type layer, and a p-type layer) is executed. In S55, the formation of an upper electrode layer AN (i.e. the deposition and patterning of a transparent conductive film TL of FIG. 7) is executed.

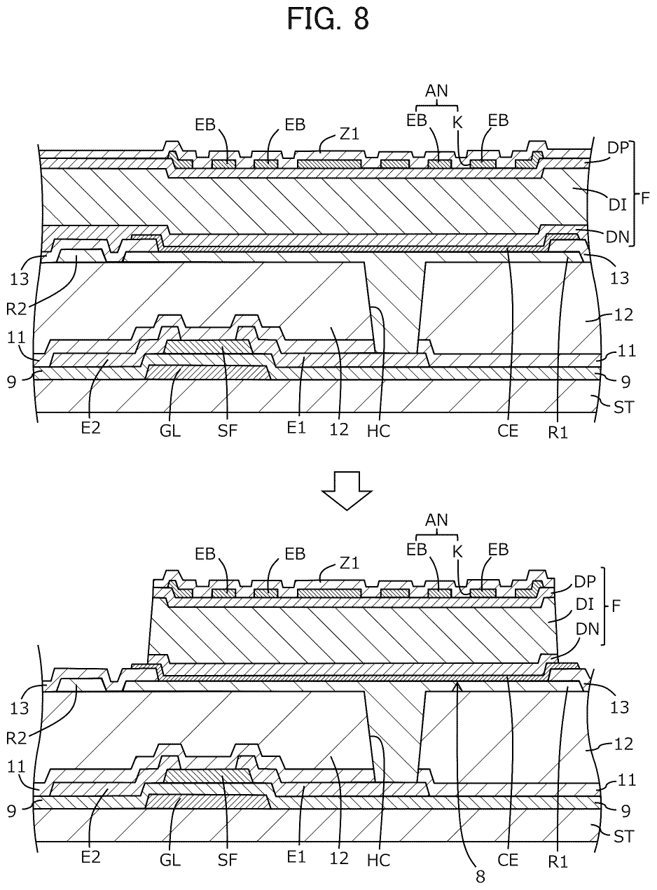

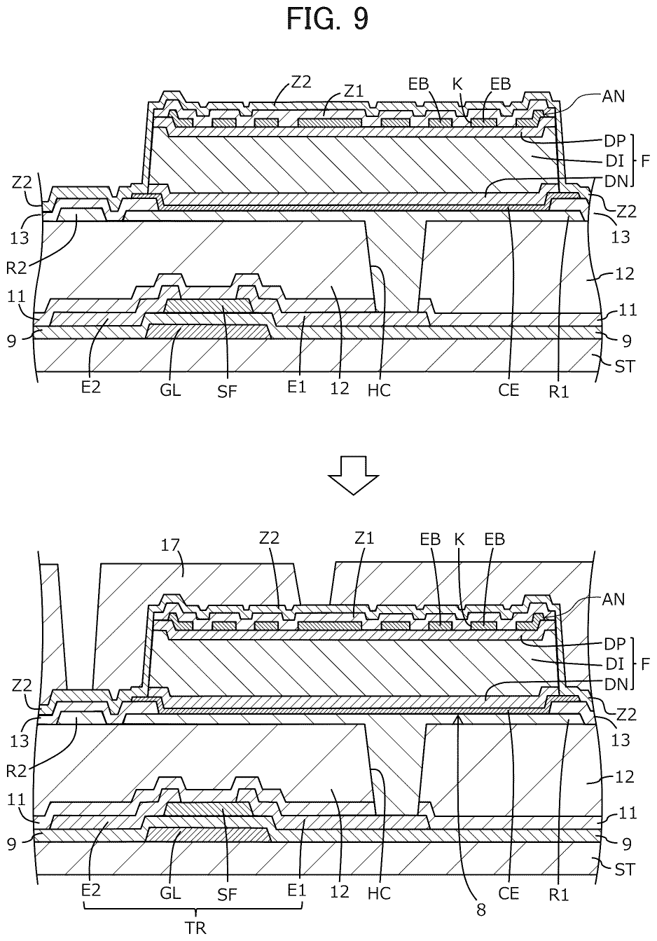

As shown in FIG. 8, in S60, the deposition of a first insulating film Z1 (i.e. the deposition of an inorganic insulating film) is executed, and in S65, the patterning of the functional layer F and the first insulating film Z1 is executed. At this stage, a side surface of the functional layer F becomes exposed. As shown in FIG. 9, in S70, the deposition of a second insulating film Z2 (i.e. the deposition of an inorganic insulating film) is executed, and in S75, the formation of a planarizing film 17 (i.e. the deposition and patterning of an organic insulating film) is executed.

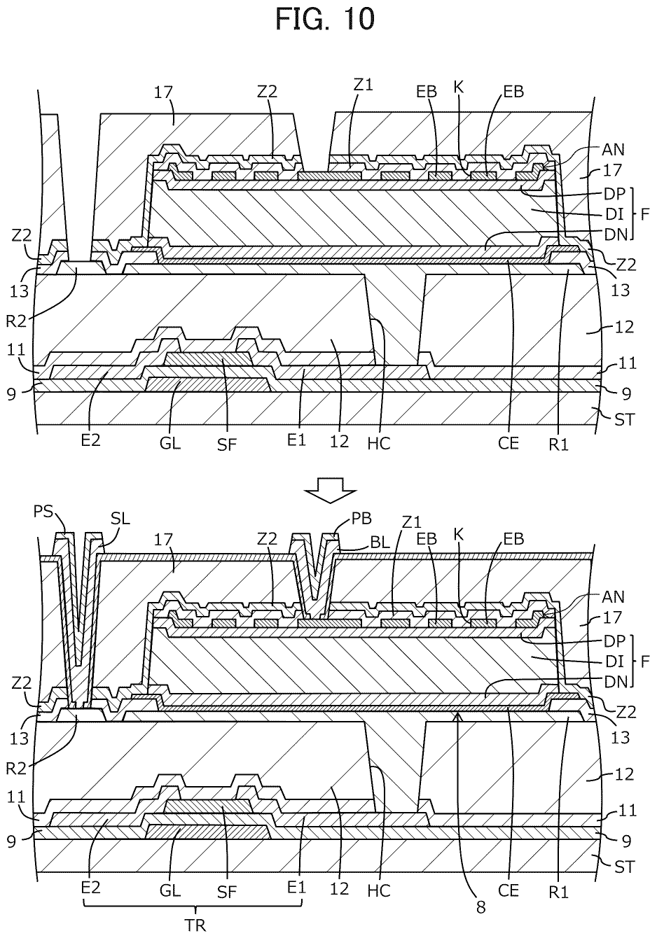

As shown in FIG. 10, in S80, the etching of the first insulating film Z1 and the second insulating film Z2 is executed, and in S82, the formation of a third insulating film Z3 (i.e. the deposition and patterning of an inorganic insulating film) is executed. In S84, the deposition of a wiring layer (i.e. the deposition of a metal film) is executed, and in S86, the deposition of a transparent conductive layer is executed. In S88, the formation (patterning) of a data line SL, a bias line BL, and transparent electrodes PB and PS is executed.

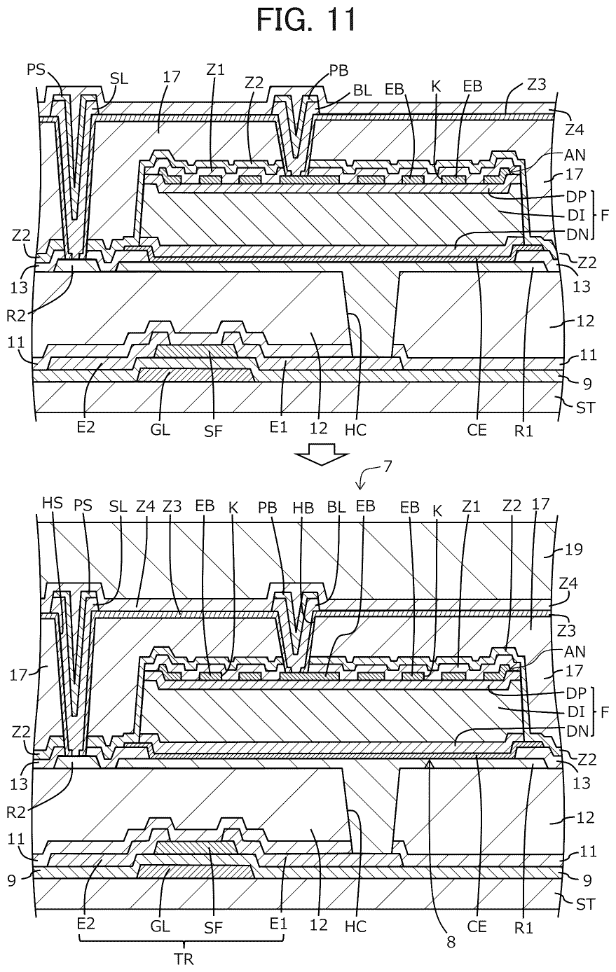

As shown in FIG. 11, in S96, the formation of a fourth insulating film Z4 (i.e. the deposition and patterning of an inorganic insulating film) is executed, and in S98, the formation of a protective film 19 (i.e. the deposition and patterning of an organic insulating film) is executed.

As shown in FIGS. 7 and 8, the present embodiment includes forming the upper electrode layer AN having an electrode section EB and an opening K and forming the first insulating film Z1 covering the opening K. As shown in FIG. 8, the upper electrode layer AN is formed (i.e. the deposition and patterning of a metal film is executed) after the functional layer F is deposited, and the functional layer F is subjected to patterning after the upper electrode layer AN is formed. This reduces the risk of side face deterioration and side face short circuit of the functional layer F. As shown in FIG. 9, a second insulating film Z2 covering a side surface of the functional layer F is formed after the functional layer F is subjected to patterning, and a planarizing film 17 is formed over the second insulating film Z2.

Adhesion between the ITO used in the upper electrode layer AN and a silicon nitride film is not high; however, in a case where an acrylic resin film is used as the interlayer insulating film 12, high-temperature deposition is infeasible, with the result that a first insulating film Z1 deposited at low temperature (e.g. a silicon nitride film) is used and, furthermore, a tensile stress is produced in a step (i.e. the formation of the planarizing film 17 and the protective film 19) subsequent to the formation of the first insulating film Z1. That is, using a solid electrode as an anode layer and forming a silicon nitride film over the solid electrode may cause a phenomenon in which the silicon nitride film delaminates. In the case of an application to an X-ray imaging apparatus, delamination of a silicon nitride film causes a decrease in diode performance and variations in the sensitivity of diodes. In the present embodiment, providing the upper electrode layer AN (anode layer) with the opening K makes it difficult for the first insulating film Z1 to delaminate from the upper electrode layer AN, making it possible to address such a problem.

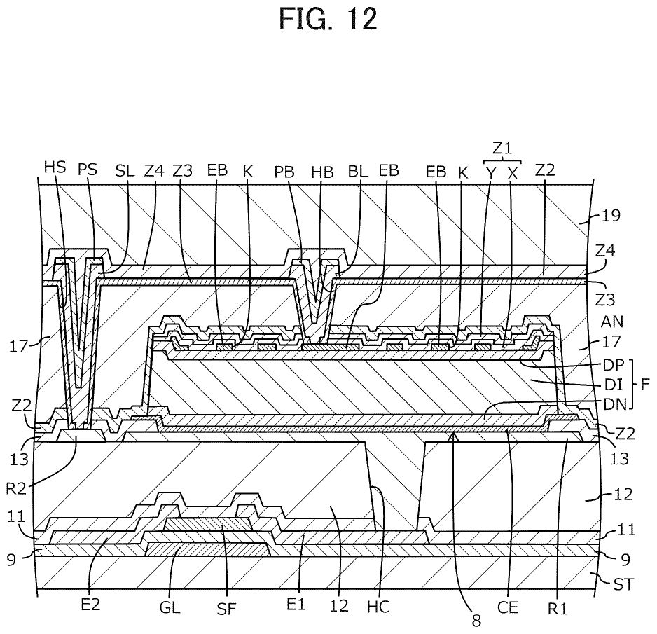

FIG. 12 is a cross-sectional view showing an example configuration of a photoelectric conversion panel according to the present embodiment. As shown in FIG. 12, the first insulating film Z1 may be a stack structure including a lower film X and an upper film Y that are in contact with the functional layer F (type 3 layer DP). In this case, the lower film X of the first insulating film Z1 may be a silicon oxide film that is higher in adhesion to the type 3 layer DP (than is a silicon nitride film), and the upper film Y of the first insulating film Z1 may be a silicon nitride film that is higher in insulation performance (than is a silicon oxide film). The lower film X may be an ultrathin film with a thickness of approximately 10 nm. In a case where the interlayer insulating film 12 is made of resin (that is resistant to a temperature of approximately 200° C., the silicon oxide film of the lower film X is formed at a low temperature (lower than 200° C.).

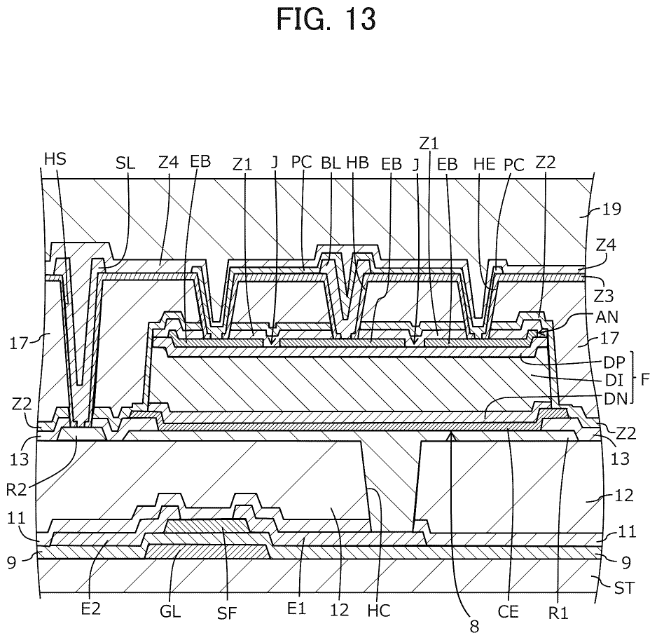

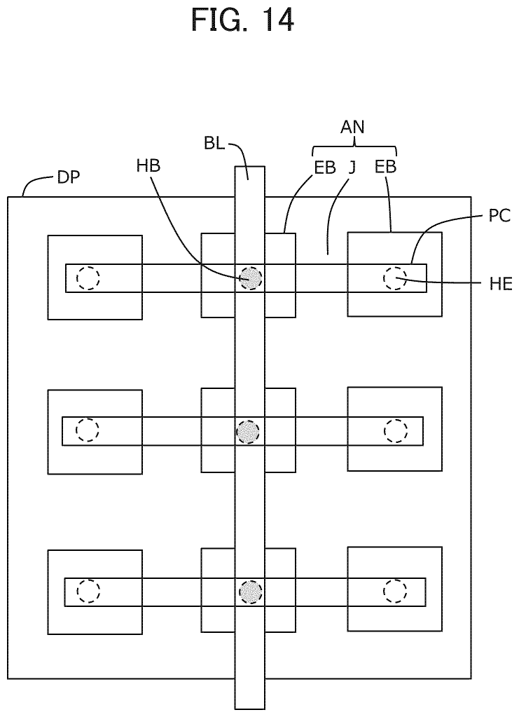

FIG. 13 is a cross-sectional view showing an example configuration of a photoelectric conversion panel according to the present embodiment. FIG. 14 is a plan view showing the example configuration of the photoelectric conversion panel according to the present embodiment. As shown in FIGS. 13 and 14, the photoelectric conversion panel 7 according to the present embodiment includes a photodiode 8 including a lower electrode layer CE and an upper electrode layer AN and a first insulating film Z1 located above the photodiode 8. The upper electrode layer AN has a plurality of electrically connected electrode sections EB that are adjacent to each other via a gap portion J, and the first insulating film Z1 covers the gap portion J.

This brings the electrode sections EB and a foundation of the upper electrode layer AN (e.g. a type 3 layer DP of the photodiode 8) into direct contact with each other in the gap portion J, thus enhancing adhesion between the first insulating film Z1 and the upper electrode layer AN. This makes it difficult for the first insulating film Z1 to delaminate from the upper electrode layer AN and brings about improvement in photoelectric conversion accuracy of the photoelectric conversion panel 7. As shown in FIG. 14, the plurality of electrode sections EB may be arranged in a matrix.

In FIGS. 13 and 14, the first insulating film Z1 and the type 3 layer DP of the functional layer F are in contact with each other in the gap portion J. The photoelectric conversion panel 7 of FIGS. 13 and 14 includes a transparent electrode PC located at a higher layer than the plurality of electrode sections EB and connected to the plurality of electrode sections EB. Specifically, the plurality of electrode sections EB are connected to the transparent electrode PC via a contact hole HE, and the transparent electrode PC and the bias line BL are connected to each other, whereby the plurality of electrode sections EB and the bias line BL are electrically connected. The transparent electrode PC may be made of a translucent metal oxide such as ITO.

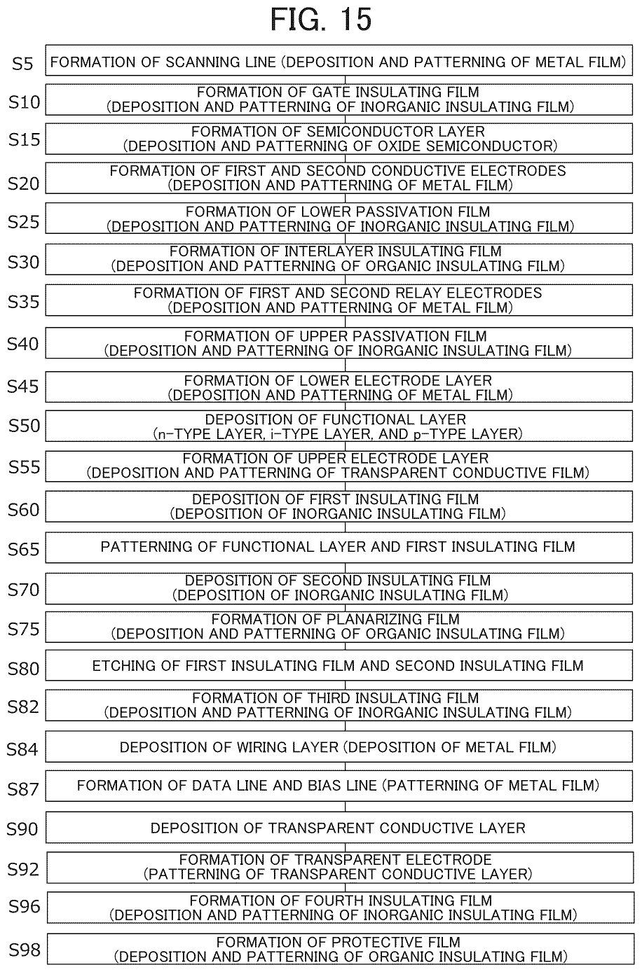

FIG. 15 is a flow chart showing a method for manufacturing a photoelectric conversion panel shown in FIGS. 13 and 14. As shown in FIGS. 13 to 15, the present embodiment includes forming the upper electrode layer AN having a plurality of electrically connected electrode sections EB that are adjacent to each other via a gap portion J (S55) and forming the first insulating film Z1 covering the gap portion J (S60 and S80).

In S84, the deposition of a wiring layer (i.e. the deposition of a metal film) is executed, and in S87, the formation of a data line SL and a bias line BL (i.e. the patterning of a metal film) is executed. In S90, the deposition of a transparent conductive layer is executed, and in S92, the formation of a transparent electrode PC (i.e. the patterning of the transparent conductive layer) is executed.

In S96, the formation of a fourth insulating film Z4 (i.e. the deposition and patterning of an inorganic insulating film) is executed, and in S98, the formation of a protective film 19 (i.e. the deposition and patterning of an organic insulating film) is executed.

The foregoing disclosure are intended for illustrative and explanatory purposes and is not intended for limitative purposes. Based of these illustrations and explanations, many modifications become self-evident to persons skilled in the art; therefore, these modifications are encompassed in the embodiment.

### CONCLUSION

A photoelectric conversion panel of Aspect 1 includes a photodiode including a lower electrode layer and an upper electrode layer and a first insulating film located over the photodiode. The upper electrode layer has an electrode section and an opening, and the first insulating film covers the opening.

A photoelectric conversion panel of Aspect 2 includes a photodiode including a lower electrode layer and an upper electrode layer and a first insulating film located over the photodiode. The upper electrode layer has a plurality of electrically connected electrode sections that are adjacent to each other via a gap portion, and the first insulating film covers the gap portion.

A photoelectric conversion panel of Aspect 3 is directed to the photoelectric conversion panel of Aspect 1, wherein the photodiode has a functional layer located between the lower electrode layer and the upper electrode layer and containing a semiconductor, in the functional layer, a type 1 layer, a type 2 layer, and a type 3 layer are stacked in this order from bottom, and the first insulating film and the type 3 layer are in contact with each other in the opening.

A photoelectric conversion panel of Aspect 4 is directed to the photoelectric conversion panel of Aspect 2, wherein the photodiode has a functional layer located between the lower electrode layer and the upper electrode layer and containing a semiconductor, in the functional layer, a type 1 layer, a type 2 layer, and a type 3 layer are stacked in this order from bottom, and the first insulating film and the type 3 layer are in contact with each other in the gap portion.

A photoelectric conversion panel of Aspect 5 is directed to the photoelectric conversion panel of Aspect 1, wherein the upper electrode layer has a group of openings including the opening, and the group of openings are arranged in a matrix.

A photoelectric conversion panel of Aspect 6 is directed to the photoelectric conversion panel of Aspect 2, further including a transparent electrode located at a higher layer than the plurality of electrode sections and connected to the plurality of electrode sections.

A photoelectric conversion panel of Aspect 7 is directed to the photoelectric conversion panel of Aspect 1, further including a bias line electrically connected to the electrode section, wherein the upper electrode layer includes a mesh region including the opening and a solid electrode region not including the opening, and the solid electrode region is connected to the bias line via a contact hole.

A photoelectric conversion panel of Aspect 8 is directed to the photoelectric conversion panel of Aspect 6, further including a bias line electrically connected to the plurality of electrode sections, wherein the bias line is in contact with the transparent electrode.

A photoelectric conversion panel of Aspect 9 is directed to the photoelectric conversion panel of any one of Aspects 1 to 8, further including a planarizing film located at a higher layer than the first insulating film.

A photoelectric conversion panel of Aspect 10 is directed to the photoelectric conversion panel of Aspect 3 or 4, further including a second insulating film covering a side face of the functional layer.

A photoelectric conversion panel of Aspect 11 is directed to the photoelectric conversion panel of any one of Aspects 1 to 10, wherein the first insulating film is a silicon nitride film.

A photoelectric conversion panel of Aspect 12 is directed to the photoelectric conversion panel of Aspect 3 or 4, wherein the first insulating film is a stack structure including a lower film and an upper film that are in contact with the functional layer.

A photoelectric conversion panel of Aspect 13 is directed to the photoelectric conversion panel of Aspect 12, wherein the lower film is a silicon oxide film, and the upper film is a silicon nitride film.

A photoelectric conversion panel of Aspect 14 is directed to the photoelectric conversion panel of Aspect 3 or 4, wherein the type 3 layer is a p-type silicon layer.

A photoelectric conversion panel of Aspect 15 is directed to the photoelectric conversion panel of any one of Aspects 1 to 14, wherein the lower electrode layer is a cathode layer, and the upper electrode layer is an anode layer.

An X-ray imaging apparatus of Aspect 16 includes the photoelectric conversion panel of any one of Aspects 1 to 15.

A method of Aspect 17 for manufacturing a photoelectric conversion panel including a photodiode including a lower electrode layer, an upper electrode layer, and a functional layer and a first insulating film located over the photodiode includes forming the upper electrode layer having an electrode section and an opening and forming the first insulating film covering the opening.

A method of Aspect 18 for manufacturing a photoelectric conversion panel including a photodiode including a lower electrode layer, an upper electrode layer, and a functional layer and a first insulating film located over the photodiode includes forming the upper electrode layer having a plurality of electrically connected electrode sections that are adjacent to each other via a gap portion and forming the first insulating film covering the gap portion.

A method of Aspect 19 is directed to the method of Aspect 17 or 18, wherein the upper electrode layer is formed after the functional layer is deposited, and the functional layer is subjected to patterning after the upper electrode layer is formed.

A method of Aspect 20 is directed to the method of Aspect 19, wherein a second insulating film covering a side face of the functional layer is formed after the functional layer is subjected to patterning.

A method of Aspect 21 is directed to the method of Aspect 20, wherein a planarizing film is formed over the second insulating film.

The present disclosure contains subject matter related to that disclosed in Japanese Priority Patent Application JP 2025-004264 filed in the Japan Patent Office on Jan. 10, 2025, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion panel comprising:
a photodiode including a lower electrode layer and an upper electrode layer; and
a first insulating film located over the photodiode,
wherein
the upper electrode layer has an electrode section and an opening, and
the first insulating film covers the opening.

2. A photoelectric conversion panel comprising:
a photodiode including a lower electrode layer and an upper electrode layer; and
a first insulating film located over the photodiode,
wherein
the upper electrode layer has a plurality of electrically connected electrode sections that are adjacent to each other via a gap portion, and
the first insulating film covers the gap portion.

3. The photoelectric conversion panel according to claim 1, wherein
the photodiode has a functional layer located between the lower electrode layer and the upper electrode layer and containing a semiconductor,
in the functional layer, a type 1 layer, a type 2 layer, and a type 3 layer are stacked in this order from bottom, and
the first insulating film and the type 3 layer are in contact with each other in the opening.

4. The photoelectric conversion panel according to claim 2, wherein
the photodiode has a functional layer located between the lower electrode layer and the upper electrode layer and containing a semiconductor,
in the functional layer, a type 1 layer, a type 2 layer, and a type 3 layer are stacked in this order from bottom, and
the first insulating film and the type 3 layer are in contact with each other in the gap portion.

5. The photoelectric conversion panel according to claim 1, wherein
the upper electrode layer has a group of openings including the opening, and
the group of openings are arranged in a matrix.

6. The photoelectric conversion panel according to claim 2, further comprising a transparent electrode located at a higher layer than the plurality of electrode sections and connected to the plurality of electrode sections.

7. The photoelectric conversion panel according to claim 1, further comprising a bias line electrically connected to the electrode section,
wherein
the upper electrode layer includes a mesh region including the opening and a solid electrode region not including the opening, and
the solid electrode region is connected to the bias line via a contact hole.

8. The photoelectric conversion panel according to claim 6, further comprising a bias line electrically connected to the plurality of electrode sections,
wherein the bias line is in contact with the transparent electrode.

9. The photoelectric conversion panel according to claim 1, further comprising a planarizing film located at a higher layer than the first insulating film.

10. The photoelectric conversion panel according to claim 3, further comprising a second insulating film covering a side face of the functional layer.

11. The photoelectric conversion panel according to claim 1, wherein the first insulating film is a silicon nitride film.

12. The photoelectric conversion panel according to claim 3, wherein the first insulating film is a stack structure including a lower film and an upper film that are in contact with the functional layer.

13. The photoelectric conversion panel according to claim 12, wherein
the lower film is a silicon oxide film, and
the upper film is a silicon nitride film.

14. The photoelectric conversion panel according to claim 3, wherein the type 3 layer is a p-type silicon layer.

15. The photoelectric conversion panel according to claim 1, wherein
the lower electrode layer is a cathode layer, and
the upper electrode layer is an anode layer.

16. An X-ray imaging apparatus comprising the photoelectric conversion panel according to claim 1.

17. A method for manufacturing a photoelectric conversion panel including a photodiode including a lower electrode layer, an upper electrode layer, and a functional layer and a first insulating film located over the photodiode, the method comprising:
forming the upper electrode layer having an electrode section and an opening; and
forming the first insulating film covering the opening.

18. A method for manufacturing a photoelectric conversion panel including a photodiode including a lower electrode layer, an upper electrode layer, and a functional layer and a first insulating film located over the photodiode, the method comprising:
forming the upper electrode layer having a plurality of electrically connected electrode sections that are adjacent to each other via a gap portion; and
forming the first insulating film covering the gap portion.

19. The method according to claim 17, wherein
the upper electrode layer is formed after the functional layer is deposited, and
the functional layer is subjected to patterning after the upper electrode layer is formed.

20. The method according to claim 19, wherein a second insulating film covering a side face of the functional layer is formed after the functional layer is subjected to patterning.

21. The method according to claim 20, wherein a planarizing film is formed over the second insulating film.
